(19) United States
(12) Patent Application Publication
(10) Pub. No.: US 2024/0014049 A1
(43) Pub. Date: Jan. 11, 2024

(54) RELEASE FILM FOR MOLD PROCESS, AND METHOD FOR MANUFACTURING THE SAME

(71) Applicant: SAMSUNG ELECTRONICS CO., LTD., Suwon-si (KR)

(72) Inventors: Chulho Jung, Suwon-si (KR); Jihan Ko, Suwon-si (KR); Kunsil Lee, Suwon-si (KR)

(73) Assignee: SAMSUNG ELECTRONICS CO., LTD., Suwon-si (KR)

(21) Appl. No.: 18/124,255

(22) Filed: Mar. 21, 2023

(30) Foreign Application Priority Data
Jul. 5, 2022 (KR) 10-2022-0082759

(51) Int. Cl. H01L 21/56; H01L 21/67

(52) U.S. Cl. CPC H01L 21/566; H01L 21/67126

(57) ABSTRACT

A release film for a mold process capable of minimizing defects of a semiconductor package in a semiconductor packaging process, and a method for manufacturing the release film for a mold process are provided. The release film for the mold process includes a base film and a plurality of conductive fillers located inside the base film and arranged on upper and/or lower surfaces of the base film, wherein roughness is formed by the plurality of conductive fillers on the upper and/or lower surfaces of the base film, and a conductive path is formed between the upper and lower surfaces of the base film.

### CROSS-REFERENCE TO RELATED APPLICATION

This application is based on and claims priority under 35 U.S.C. § 119 to Korean Patent Application No. 10-2022-0082759, filed on Jul. 5, 2022, in the Korean Intellectual Property Office, the disclosure of which is incorporated by reference herein in its entirety.

### BACKGROUND

### 1. Field

Embodiments of the present disclosure relate to a release film and a method for manufacturing the same, and more particularly, to a release film for a mold process used in a mold process of a semiconductor package, and a method for manufacturing the same.

### 2. Description of the Related Art

In a mold process of a semiconductor packaging process, semiconductor chips may be sealed with a molding resin. As a molding resin, epoxy molding compound (EMC) is mainly used. The mold process, or molding, is simpler and more productive than any other processing method, and is currently most commonly used in the semiconductor packaging process. Molding resins, such as EMC, are inferior in thermal stability and reliability, compared to ceramic materials, but they are inexpensive and highly productive, so they are currently used in most semiconductor packaging processes. Meanwhile, in a semiconductor packaging process, a molding resin may be injected into a mold to seal semiconductor chips, and in this process, the molding resin may be attached to a surface of the mold, thereby contaminating the mold and causing other semiconductor packages to be defective.

### SUMMARY

In order to address a problem of the related art, a release film may be attached to a mold so that a molding resin may not directly contact a surface of the mold to prevent contamination.

Embodiments of the present disclosure provide a release film for a mold process, capable of minimizing defects of a semiconductor package in a semiconductor packaging process, and a method for manufacturing the same.

In addition, the problems to be solved by embodiments of the present disclosure are not limited to the problems mentioned above, and other problems and solutions may be clearly understood by those skilled in the art from the following description.

According to embodiments of the present disclosure, a release film for a mold process is provided. The release film includes: a base film; and a plurality of conductive fillers that are in or on the base film, the plurality of conductive fillers including external conductive fillers that are on at least one from among an upper surface and a lower surface of the base film, such that the external conductive fillers provide roughness to the at least one from among the upper surface and the lower surface of the base film, wherein a conductive path is formed between the upper surface and the lower surface of the base film.

According to embodiments of the present disclosure, a release film for a mold process is provided. The release film includes: a base film as a monolayer; and a plurality of conductive fillers, the plurality of conductive fillers including: internal conductive fillers inside the base film; first external conductive fillers on an upper surface of the base film; and second external conductive fillers on a lower surface of the base film, wherein at least a portion of the first external conductive fillers and at least a portion of the second external conductive fillers protrude from the upper surface and the lower surface of the base film, respectively, and wherein the first external conductive fillers on the upper surface are connected to the second external conductive fillers on the lower surface through the internal conductive fillers that are inside the base film.

According to embodiments of the present disclosure, a method for manufacturing a release film is provided. The method includes: preparing a resin for a base film; obtaining a resin-filler mixture by mixing a plurality of conductive fillers with the resin; and obtaining the release film in a form of a thin film using the resin-filler mixture, wherein the release film includes the base film, as a monolayer, and the plurality of conductive fillers, wherein the plurality of conductive fillers are in or on the base film, and the plurality of conductive fillers includes external conductive fillers that are on at least one from among an upper surface and a lower surface of the base film, such that the external conductive fillers provide roughness to the at least one from among the upper surface and the lower surface of the base film, and wherein a conductive path is formed between the upper surface and the lower surface of the base film.

### BRIEF DESCRIPTION OF DRAWINGS

Embodiments will be more clearly understood from the following detailed description taken in conjunction with the accompanying drawings in which:

FIG. 1A is a side view of a release film for a mold process according to an embodiment;

FIG. 1B is a cross-sectional view of the release film for the mold process according to an embodiment;

FIGS. 2A to 2C are conceptual views illustrating a process of giving roughness to a sealing material in a semiconductor packaging process using the release film for a mold process of FIG. 1A;

FIGS. 3A to 3F are conceptual views illustrating various types of conductive fillers included in the release film for a mold process of FIG. 1A;

FIG. 4A is a flowchart illustrating a process of manufacturing a conductive filler included in the release film for a mold process of FIG. 1A;

FIGS. 4B to 4D are conceptual diagrams corresponding to respective operations of the flowchart of FIG. 4A;

FIGS. 5A and 5B are cross-sectional views of a release film for a mold process according to embodiments;

FIG. 6 is a flowchart schematically illustrating a process of a method for manufacturing a release film according to an embodiment;

FIG. 7A is a flowchart illustrating in more detail an operation of producing a resin-filler mixture based on an extrusion method in the method for manufacturing a release film of FIG. 6;

FIG. 7B is a conceptual diagram of an extrusion apparatus used in the operation of manufacturing a release film in the form of a thin film;

FIG. 8A is a flowchart illustrating in more detail an operation of producing a resin-filler mixture based on a casting method in the method for manufacturing a release film of FIG. 6.

FIG. 8B is a conceptual diagram of a casting process corresponding to the flow chart of FIG. 8A; and

FIG. 8C is a conceptual diagram of a casting process used in an operation of manufacturing a release film in the form of a thin film.

### DETAILED DESCRIPTION

Hereinafter, non-limiting example embodiments are described in detail with reference to the accompanying drawings. The same reference numerals are used for the same components in the drawings, and redundant descriptions thereof are omitted.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element or layer is referred to as being “directly over,” “directly above,” “directly on,” “directly below,” “directly under,” “directly beneath,” “directly connected to” or “directly coupled to” another element or layer, there are no intervening elements or layers present.

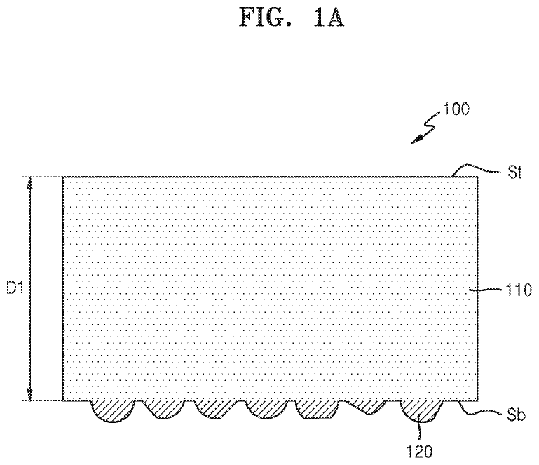

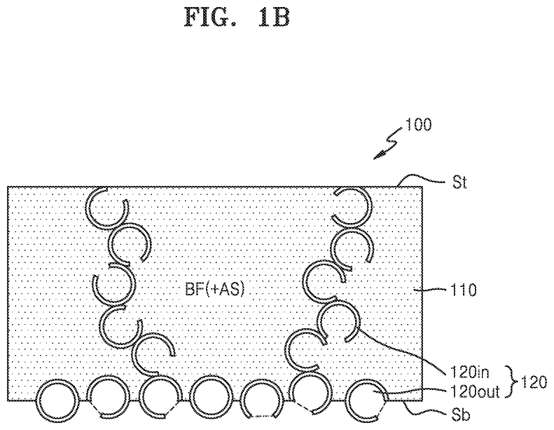

FIGS. 1A and 1B are a side view and a cross-sectional view of a release film 100 for a mold process according to an embodiment.

Referring to FIGS. 1A and 1B, the release film 100 for a mold process of the present embodiment may include a base film 110 and a conductive filler 120. In general, a release film is a film used for the purpose of product protection, and refers to a film that may be easily peeled off when used. The release film 100 of the present embodiment is a film for protecting a mold during a mold process, and may be attached to an inner surface of the mold to be used. In addition, the release film 100 of the present embodiment may include only the base film 110 as a monolayer and a plurality of the conductive filler 120 added thereto, without a separate adhesive layer. Accordingly, the release film 100 of the present embodiment may be attached to the mold through vacuum suction, not the adhesiveness of an adhesive layer. In addition, the release film 100 of the present embodiment may be easily peeled off from the mold by releasing the vacuum.

The base film 110 may be formed based on resins generally used in a release film for a mold process. For example, in the release film 100 of the present embodiment, the base film 110 may include an ethylene tetrafluoroethylene (ETFE) resin, a polyethylene terephthalate (PET) resin, a polybutylene terephthalate (PBT) resin, or a poly tetrafluoroethylene (PTTE) resin. However, a material of the base film 110 is not limited to the above materials. In addition, in the release film 100 of the present embodiment, a thickness D1 of the base film 110 may be about 30 μm to about 150 μm. However, the thickness D1 of the base film 110 is not limited to the above numerical range.

For reference, a release film of a comparative embodiment may generally have a multi-layer structure. In the case of the release film, an extrusion method may be used to give roughness to the film. For example, in the extrusion method, roughness may be given to the release film through a roll-to-roll (R2R) process. However, for the extrusion method, only expensive ETFE, PET, and PBT resins are available. In addition, there is a casting method as a film manufacturing method, and the casting method may use a relatively inexpensive PTFE resin. However, in the case of the casting method, although roughness may be given through coating, a multi-step process is required, which may lead to an increase in manufacturing cost. Because there is no process for giving roughness thereto, the casting method cannot be used for manufacturing a release film.

In the case of a multilayer release film according to a comparative embodiment, an antistatic layer (AS) layer for electrostatic discharge (ESD) prevention may be required. Therefore, because a process for coating the AS layer on the base film has to be performed, this may be disadvantageous in terms of cost and time. In addition, because there is no strong bond, such as covalent bonding between the AS layer and the base film, peeling may frequently occur between the AS layer and the base film during the mold process, which may interfere with continuous workability of the mold process. Furthermore, adhesion of the AS layer to the surface of the mold may cause a defect in the release film and also contaminate the surface of the mold.

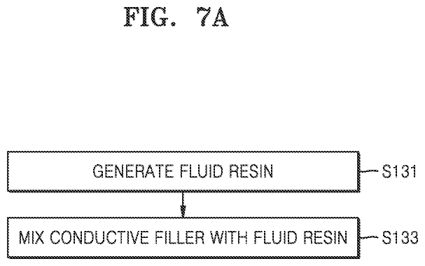

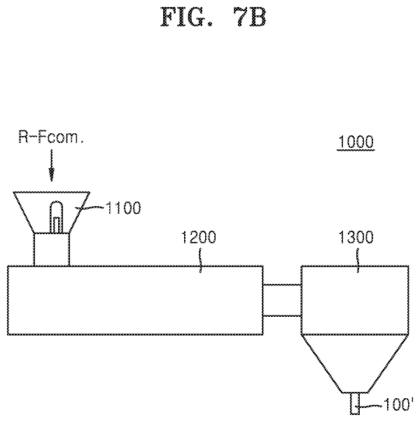

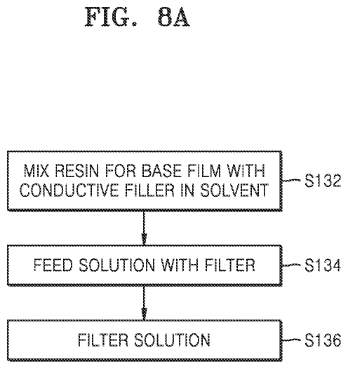

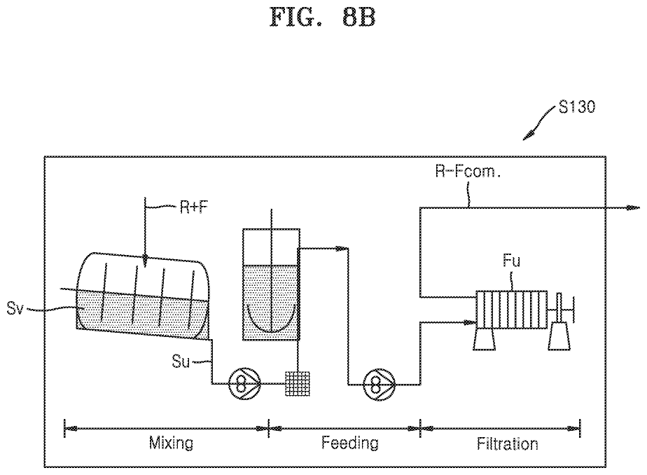

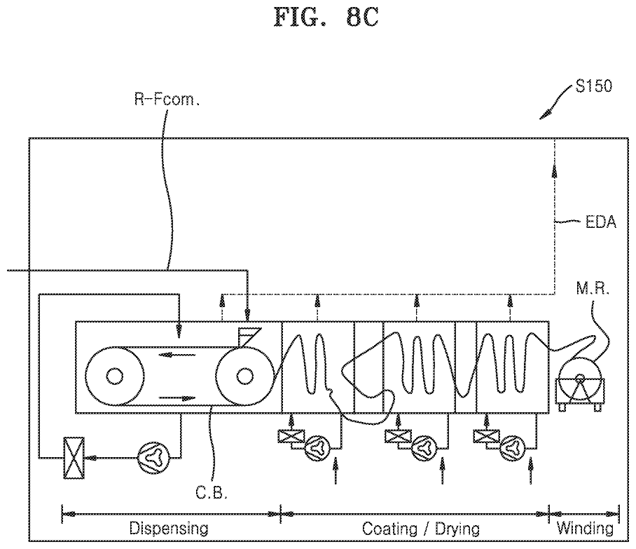

However, in the case of the release film 100 of the present embodiment, because roughness is formed by the conductive filler 120, a separate roughness giving process is unnecessary, and therefore, both an injection method and the casting method may be used. As a result, the release film 100 of the present embodiment may use an inexpensive PTFE resin as the base film 110. In relation to the manufacturing of the release film 100 of the present embodiment, the injection method and the casting method are described in more detail below with reference to FIGS. 7A to 8C.

Because the release film 100 of the present embodiment has a single-layer structure, cost and time may be reduced by skipping an AS layer coating process. In addition, due to the single-layer structure of the release film 100 of the present embodiment, the peeling between the AS layer and the base film may be solved, thereby improving continuous workability of the mold process.

Meanwhile, a material of the base film 110 is described in terms of curing as follows. That is, the base film 110 may be formed of an ultraviolet (UV)-curable resin. Here, the UV-curable resin may refer to a resin that may be UV-cured. The UV-curable resin may include, for example, at least one selected from urethane acrylate, polyester acrylate, polyether, acrylic acrylate, epoxy acrylate, and fluorinated acrylate. Moreover, the base film 110 may further include a thermosetting resin in the ultraviolet curable resin. In the case of such a base film 110, double curing may be performed by UV rays and heat, and accordingly, a curing speed may increase.

The base film 110 may be formed of a thermosetting resin. Here, the thermosetting resin may refer to a resin that may be cured by heat. The thermosetting resin may include, for example, at least one selected from an epoxy resin, a vinyl resin, and an allyl resin. The thermosetting resin may undergo a crosslinking reaction by a curing agent under high temperature conditions, and thus, a curing reaction may proceed.

The epoxy resin may include, for example, a bisphenol F epoxy resin, a cresol novolac epoxy resin, a phenol novolac epoxy resin, a biphenyl epoxy resin, a stilbene epoxy resin, a hydroquinone epoxy resin, a naphthalene epoxy resin, a tetraphenylolethane epoxy resin, a DPP epoxy resin, a trishydroxyphenylmethane epoxy resin, a dicyclopentadienephenol type epoxy resin, and the like, but is not limited thereto. In addition, the vinyl resin may include, for example, a resin having a 1,2-vinyl group, a cis 1,4-vinyl group, and a trans 1,4-vinyl group in a molecule, but is not limited thereto.

The conductive filler 120 may be spread and distributed throughout the base film 110. In other words, the conductive filler 120 may be spread and distributed on an upper surface St and a lower surface Sb of the base film 110 and throughout the inside of the base film 110. As shown in FIGS. 1A and 1B, the conductive filler 120 may be disposed such that at least a portion thereof protrudes on the upper surface St and/or the lower surface Sb of the base film 110. The conductive filler 120 may be disposed to have a protruding structure on the upper surface St and/or the lower surface Sb of the base film 110, so that the conductive filler 120 may form roughness on the upper surface St and/or the lower surface Sb of the base film 110. Here, the upper surface St of the base film 110 may refer to a surface attached to the mold, and the lower surface Sb of the base film 110 may refer to a surface in contact with the molding resin in the mold process.

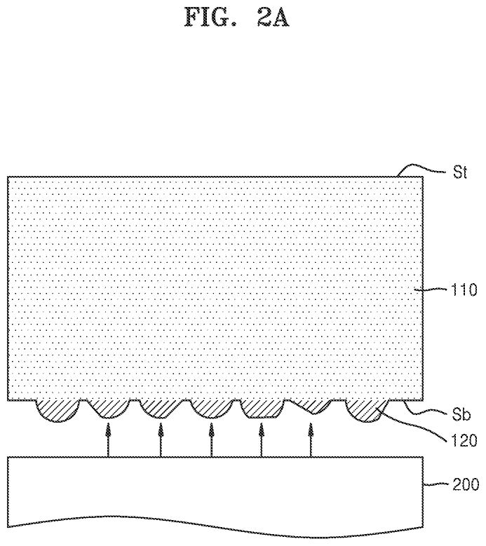

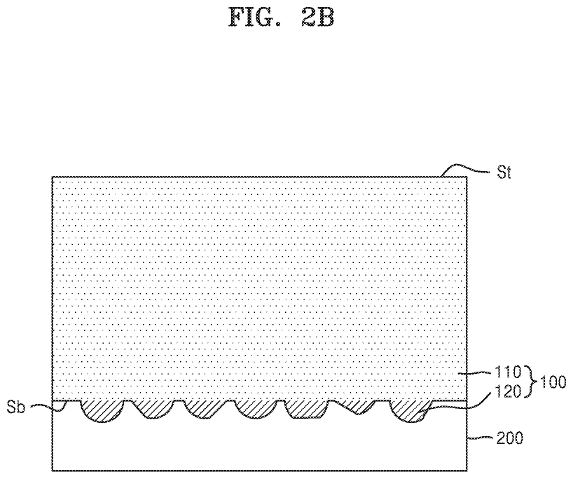

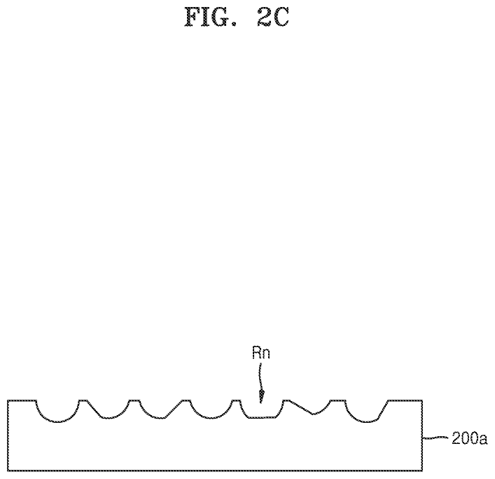

In the release film 100 of the present embodiment, the conductive filler 120 may be disposed to have a protruding structure on the lower surface Sb of the base film 110. In addition, the conductive filler 120 may include an external conductive filler 120out located in a protruding structure on the lower surface Sb of the base film 110 and an internal conductive filler 120in located inside the base film 110. The release film 100 of the present embodiment may give roughness to the surface of the molding resin by transferring roughness formed on the lower surface Sb of the base film 110 to the surface of the molding resin in the mold process. As such, because the release film 100 of the present embodiment gives roughness to the surface of the molding resin during the mold process, defects, such as chip transparency, in a semiconductor package sealed with the molding resin may be prevented. A process of transferring the roughness of the lower surface Sb of the base film 110 to the surface of the molding resin to give roughness to the molding resin is described in more detail with reference to FIGS. 2A to 2C below.

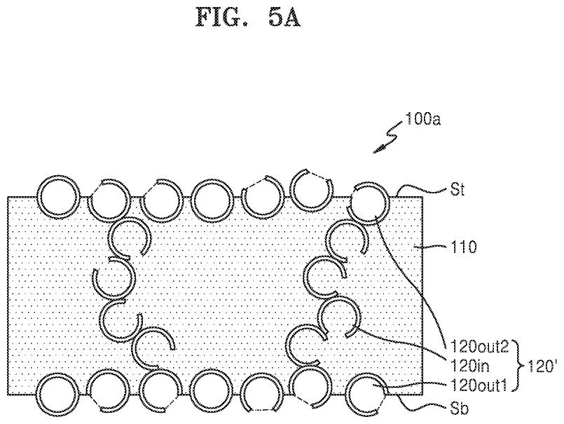

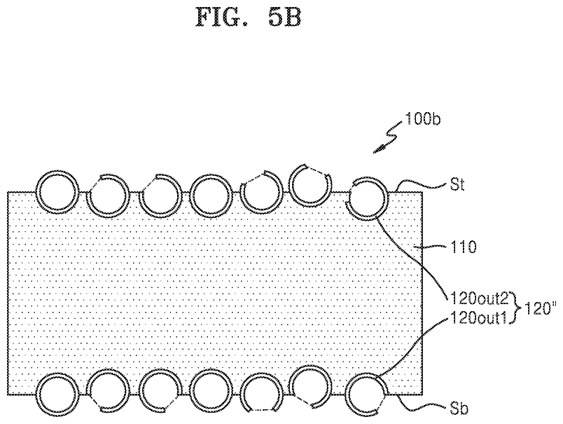

When the conductive filler 120 protrudes from both the upper surface St and the lower surface Sb of the base film 110, there is no need to clearly distinguish between the upper surface St and the lower surface Sb of the base film 110. A case in which the conductive filler 120 protrudes from both the upper surface St and the lower surface Sb of the base film 110 is described in detail below with reference to FIGS. 5A and 5B, the release film 100a, and the release film 100b.

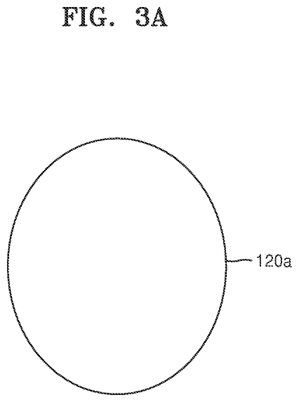

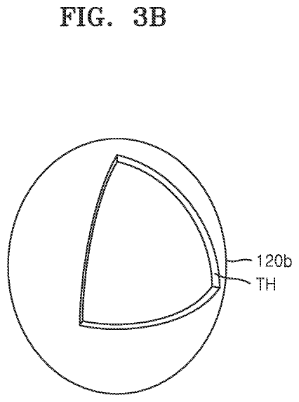

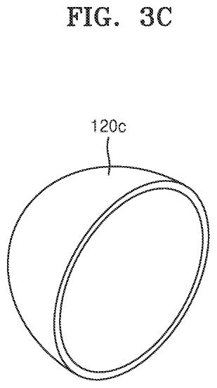

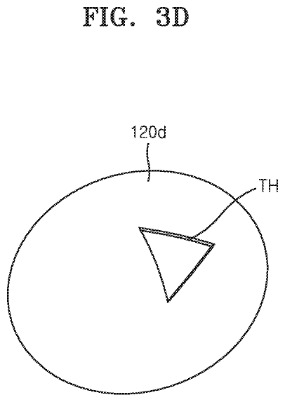

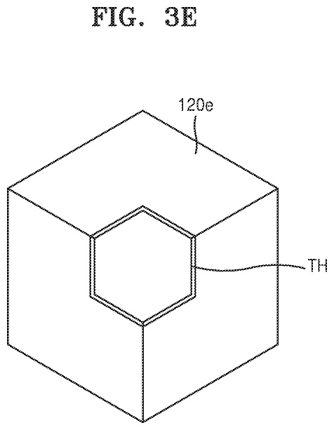

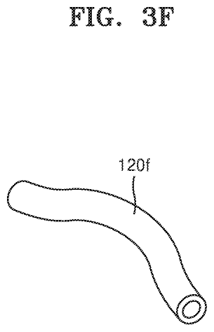

The conductive filler 120 may have various shapes to form roughness on the upper surface St and/or the lower surface Sb of the base film 110. For example, as shown in FIG. 1B, in the release film 100 of the present embodiment, the conductive filler 120 may be a hollow conductive filler having an empty inside. In addition, the conductive filler 120 may include an open hole exposing the inside. Various shapes of the conductive filler 120 are described in more detail with reference to FIGS. 3A to 3F. In addition, in the release film 100 of the present embodiment, the inside of the internal conductive filler 120in may be filled with a material of the base film 110. Also, the inside of the external conductive filler 120out may also be at least partially filled with the material of the base film 110. However, according to an embodiment, the inside of the external conductive filler 120 may not be filled with the material of the base film 110 and may be maintained empty.

As can be seen from FIG. 1B, the conductive filler 120 may be disposed in the entire inside of the base film 110 and connected to each other, so that a conductive path may be formed between the upper surface St and the lower surface Sb of the base film 110. Because the conductive filler 120 forms the conductive path between the upper surface St and the lower surface Sb of the base film 110, the release film 100 may perform an electrostatic discharge (ESD) preventing function during the mold process. In other words, because the mold is a metal and the conductive filler 120 forms the conductive path between the upper surface St and the lower surface Sb of the base film 110, a current may flow externally through the release film 100 and the mold during the mold process, thereby preventing ESD. Therefore, the release film 100 of the present embodiment may prevent ESD defects of a semiconductor package.

For the ESD preventing function, the conductive filler 120, as the term itself indicates, may be conductive. The conductive filler 120 may be divided into a metal-based filler and a carbon-based filler. The metal-based filler may include, for example, a metal filler and a metal oxide filler having conductivity. In addition, the carbon-based filler may include carbon black (CB), carbon fiber (CF), carbon nanotube (CNT), and the like. However, the material of the conductive filler 120 is not limited to the materials described above.

For reference, CB is a black, fine carbon powder. CB is similar to graphite, and carbon particles may have a size of about 1 nm to about 500 nm. Such CB may be mixed with thermosetting and thermoplastic resins for color, coloration, or other functional purposes, and may be produced in various types by combining particle size, an agglomerated structure, and surface chemical properties.

CF is a material that is lighter than steel and is ten times stronger than steel. CF may be used as an alternative material in most industries where iron is used. In particular, CF may be utilized in the manufacture of hydrogen fuel tanks that may withstand high pressure.

CNT is a new material in the form of a cylinder in which hexagons made of six carbons are connected to each other to form a tube. CNT is a material having excellent strength, modulus of elasticity, abrasion resistance, and excellent electrical and thermal conductivity, and is a material that may be either electrically conductive or a semiconductor depending on an angle at which CNT is rolled or a length of a tube diameter. Because CNT has excellent physical properties and chemical stability, CNT may be used to make a resin with strong electrical conductivity.

In addition, CNT may manifest excellent conductivity even by a very small amount, compared to CB and CF. Due to these characteristics of CNT, CNT has been widely used in aircrafts, automobile wear-resisting materials, lightweight materials, aerospace, and sports and leisure products, and have become prominent as a material leading the future.

The release film 100 of the present embodiment may prevent the molding resin from directly contacting the mold during the mold process of the semiconductor packaging process, thereby preventing contamination of the mold. In addition, the release film 100 of the present embodiment may have roughness on the lower surface Sb of the base film 110 due to the plurality of the conductive filler 120 arranged in a protruding structure on the lower surface Sb of the base film 110. The roughness on the lower surface Sb of the base film 110 may be transferred to the surface of the molding resin during the mold process. Accordingly, the molding resin may have roughness on a surface thereof, and thus, defects, such as chip transparency of the semiconductor package sealed with the molding resin, may be prevented. Furthermore, the release film 100 of the present embodiment may have the conductive path provided between the upper surface St and the lower surface Sb of the base film 110 through the conductive filler 120 provided on the upper surface St and the lower surface Sb and distributed inside thereof. Accordingly, the release film 100 of the present embodiment may prevent ESD during the mold process and effectively prevent ESD defects of a semiconductor package.

FIGS. 2A to 2C are conceptual views illustrating a process of giving roughness to a sealing material in a semiconductor packaging process using the release film for a mold process of FIG. 1A. The description given above with reference to FIGS. 1A and 1B is briefly given or omitted.

Referring to FIG. 2A, in the mold process of the semiconductor packaging process, the release film 100 of the present embodiment may be attached to an inner surface of a mold through vacuum suction. Also, in the mold process, a molding resin 200 may be injected into the mold to seal a semiconductor chip. In the release film 100 of FIG. 2A, the upper surface St of the base film 110 may be attached to the mold, and the lower surface Sb of the base film 110 may face the molding resin 200. Moreover, in the release film 100 of the present embodiment, roughness by the conductive filler 120 may be formed on the lower surface Sb of the base film 110.

Referring to FIG. 2B, as the inside of the mold is filled with the molding resin 200, the molding resin 200 may seal semiconductor chips of the semiconductor package. During a sealing process by the molding resin 200, the release film 100 and the molding resin 200 may contact each other. In other words, the lower surface Sb of the base film 110 of the release film 100 may be in contact with the surface of the molding resin 200. In the mold process, the molding resin 200 may be fluid to a degree. Accordingly, as the release film 100 joins the molding resin 200, the roughness on the lower surface Sb of the base film 110 may be transferred to the surface of the molding resin 200.

Referring to FIG. 2C, after semiconductor chips of the semiconductor package are sealed with the molding resin 200, the mold may be separated from the molding resin 200 and roughness Rn may be formed on the surface of a molding resin 200a. The roughness Rn on the surface of the molding resin 200a may have a curvature opposite to that of the lower surface Sb of the base film 110 of the release film 100. For example, when the roughness on the lower surface Sb of the base film 110 has a convex shape, the roughness Rn on the surface of the molding resin 200a may have a concave shape. In addition, the roughness Rn on the surface of the molding resin 200a may prevent chip transparency in the semiconductor package sealed by the molding resin 200.

For reference, chip transparency may occur as a thickness of the molding resin is reduced in the mold process due to a reduction in weight, thickness, length, and size of the semiconductor package. However, in the release film 100 of the present embodiment, by giving roughness to the surface of the molding resin 200a in the mold process, diffused reflection of light may occur on the surface of the molding resin 200a, and accordingly, the chip transparency may be removed.

FIGS. 3A to 3F are conceptual views illustrating various types of conductive fillers included in the release film for a mold process of FIG. 1A. The description given above with reference to FIGS. 1A to 2C is briefly given or omitted.

Referring to FIG. 3A, in the release film 100 of the present embodiment, a conductive filler 120a included in the base film 110 may have a spherical shape. In addition, the conductive filler 120a may have a hollow sphere, or a spherical shell shape. However, according to an embodiment, the conductive filler 120a may have a solid spherical shape.

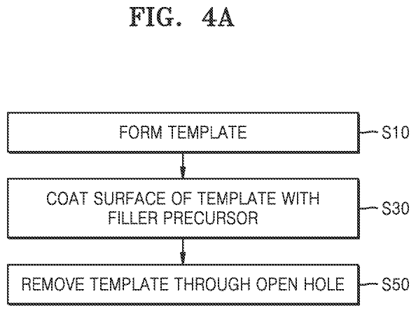

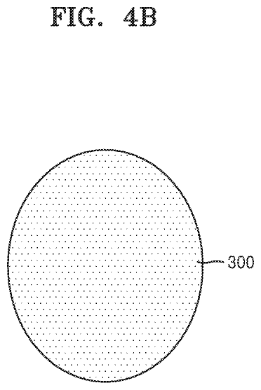

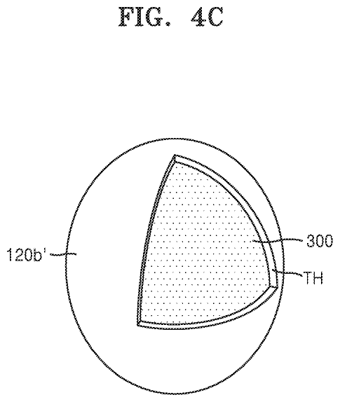

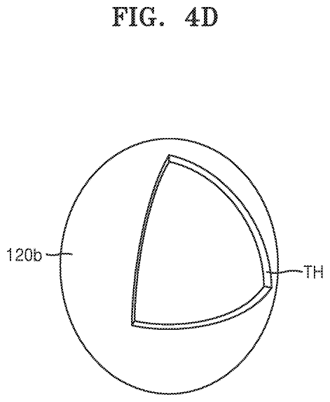

Referring to FIG. 3B, in the release film 100 of the present embodiment, a conductive filler 120b included in the base film 110 may have a spherical shape, but may include an open hole TH. In other words, the conductive filler 120b may have a hollow spherical shell shape, but may include the open hole TH exposing the inside. The open hole TH may be used to remove an internal template in the process of manufacturing the conductive filler 120b. The manufacturing process of the conductive filler 120b of the present embodiment is described in more detail with reference to FIGS. 4A to 4D below. Although the open hole TH has a substantially triangular shape in FIG. 3B, the shape of the open hole TH is not limited thereto. For example, the open hole TH may have a circular shape or a polygonal shape other than a triangle.

Referring to FIG. 3C, in the release film 100 of the present embodiment, a conductive filler 120c included in the base film 110 may have a hemispherical shape. In addition, the conductive filler 120c may have a hollow hemisphere, or a hemispherical shell shape. However, according to an embodiment, the conductive filler 120c may have a solid hemispherical shape.

Referring to FIG. 3D, in the release film 100 of the present embodiment, the conductive filler 120d included in the base film 110 may have an oval shape. In addition, the conductive filler 120d may have a hollow ellipsoidal sphere, or an ellipsoidal shell shape. However, according to an embodiment, the conductive filler 120d may have a solid ellipsoidal shape. According to embodiments, the conductive filler 120d may include an open hole TH.

Referring to FIG. 3E, in the release film 100 of the present embodiment, the conductive filler 120e included in the base film 110 may have a rectangular parallelepiped or quadrangular prism shape. In addition, the conductive filler 120e may have a hollow interior, a hollow rectangular parallelepiped, or a rectangular parallelepiped shell shape. Meanwhile, as shown in FIG. 3E, the conductive filler 120e may include an open hole TH. In other words, the conductive filler 120e may have an empty inside, a rectangular parallelepiped shell shape, and may include the open hole TH exposing the inside.

Meanwhile, in FIG. 3E, a rectangular filler shape is exemplified as a conductive filler 120e, but in the release film 100 of the present embodiment, the shape of the conductive filler is not limited to the rectangular filler shape. For example, in the release film 100 of the present embodiment, the conductive filler 120e may have various polyhedral shapes, such as a triangular pyramid, a triangular prism, and an octahedron.

Referring to FIG. 3F, in the release film 100 of the present embodiment, a conductive filler 120f included in the base film 110 may have a tube shape. In other words, the conductive filler 120f may have a hollow, circular tube shape. According to an embodiment, the conductive filler may have a fiber shape, similar to a circular tube shape. Here, the circular tube shape and the fiber shape may be distinguished from each other depending on whether the inside thereof is empty.

Meanwhile, in FIG. 3F, as the conductive filler 120f, a circular tube shape having a circular cross-section is illustrated, but in the release film 100 of the present embodiment, the conductive filler 120f is not limited to the circular tube shape. For example, in the release film 100 of the present embodiment, the conductive filler 120f may have various polygonal tube shapes having a polygonal cross-sectional shape, such as a triangle or a square.

Up to this point, various shapes of the conductive filler included in the base film 110 of the release film 100 of the present embodiment have been described. However, in the release film 100 of the present embodiment, the shape of the conductive filler included in the base film 110 is not limited to the shapes described above. For example, the conductive filler is not limited to a sphere, a hemisphere, or an elliptical sphere which is solid, and may have a polyhedral shape, such as a triangular pyramid, triangular prism, or quadrangular prism which is solid. In addition, the conductive filler may have a shape without an open hole, while having a hollow shell shape. Meanwhile, the conductive filler may have a size of several tens to several hundreds of nm. However, the size of the conductive filler is not limited to the numerical range mentioned above.

FIGS. 4A to 4D are a flowchart illustrating a process of manufacturing a conductive filler included in the release film for a mold process of FIG. 1A, and conceptual diagrams corresponding to respective operations of the flowchart. Here, the conductive filler may be, for example, the conductive filler 120b of FIG. 3B.

Referring to FIGS. 4A and 4B, first, a template 300 is formed (S10). The template 300 may include various materials. The template 300 may include a material that may be easily removed by a chemical method, such as etching, or a physical method, such as high temperature degradation. For example, the template 300 may be formed using silica, metal organic frameworks (MOF), SiO₂, an alumina membrane, or the like. The material of the template 300 is not limited to the materials described above.

Meanwhile, in FIG. 4B, the template 300 is illustrated to have a spherical shape, but the shape of the template 300 is not limited to the spherical shape. For example, the template 300 may be formed to have various shapes, such as an elliptical sphere, or a polyhedron, such as a triangular pyramid, triangular prism, or quadrangular prism. Based on the outer shape of the template 300, the shape of the conductive filler may be determined.

Referring to FIGS. 4A and 4C, the surface of the template 300 is coated with a filler precursor 120b′ (S30). The filler precursor 120b′ is a material for making the conductive filler 120b described above, and may include a metal source material, a metal oxide source material, a carbon source material, etc., depending on the material of the conductive filler 120b to be produced. A surface of the template 300 may be coated with the filler precursor 120b′ to form a template-filler complex.

Meanwhile, as shown in FIG. 4C, the filler precursor 120b′ may surround the surface of the template 300 and may include an open hole TH exposing the template 300. The open hole TH may be formed naturally during the process of coating the surface of the template 300 with the filler precursor 120b′, or may be chemically or physically intentionally formed during a curing process, after coating the entire surface of the template 300 with the filler precursor 120b′.

Referring to FIGS. 4A and 4D, thereafter, the template 300 is removed from the template-filler complex through the open hole TH (S50). The template 300 may be removed by a physical and/or chemical method depending on the material of the template 300. For example, when the template 300 is formed of silica, the template 300 may be removed by etching with an etchant, such as HF. The conductive filler 120b may be completed by removing the template 300.

Up to this point, a method for manufacturing the conductive filler 120b of FIG. 3B, which is hollow, has been briefly described using the template method, and in the release film 100 of the present embodiment, the manufacturing method for the conductive filler is not limited to the template method described above. For example, recently, various methods for manufacturing a hollow conductive filler using a template method have been researched and developed. In particular, in the case of a carbon-based conductive filler, various template materials and filler precursor materials have been developed. In addition, methods for manufacturing various types of conductive fillers, such as spheres, ellipsoids, polyhedrons, tubes, hemispheres, or bowls, using a template method, have been researched and developed based on such materials. Therefore, various methods of manufacturing the conductive filler using the aforementioned template method may also be used in the method for manufacturing the conductive filler of the release film 100 of the present embodiment.

Meanwhile, in the release film 100 of the present embodiment, the method for manufacturing the conductive filler is not limited to the template method. For example, in the release film 100 of the present embodiment, the conductive filler may be manufactured through a spraying method. For reference, the spraying method may refer to a method for making a conductive filler by forming a filler precursor in a gaseous form and then curing the filler precursor through a spraying process. The conductive filler formed by the spraying method may be hollow or solid depending on properties of the material and synthesis conditions (e.g., solvent, temperature, time, etc.).

FIGS. 5A and 5B are cross-sectional views of a release film 100a for a mold process according to embodiments, and may correspond to FIG. 1B. The description given above with reference to FIGS. 1A to 4C is briefly given or omitted.

Referring to FIG. 5A, the release film 100a of the present embodiment may be different from the release film 100 of FIG. 1B in that a conductive filler 120′ is disposed in a protruding structure even on the upper surface St of the base film 110. In an embodiment, the release film 100a of the present embodiment may include the base film 110 and the conductive filler 120′. In addition, the conductive filler 120′ may include a first external conductive filler 120out1 on the lower surface Sb of the base film 110, a second external conductive filler 120out2 on the upper surface St of the base film 110, and an internal conductive filler 120in inside the base film 110.

The first external conductive filler 120out1 may be disposed on the lower surface Sb of the base film 110 in a structure in which at least a portion thereof protrudes. The second external conductive filler 120out2 may be disposed on the upper surface St of the base film 110 in a structure in which at least a portion thereof protrudes. The internal conductive filler 120in may be evenly distributed throughout the inside of the base film 110. In addition, the first external conductive filler 120out1 may be connected to the second external conductive filler 120out2 by the internal conductive filler 120in. Accordingly, the base film 110 may include a conductive path by the conductive filler 120′ between the upper surface St and the lower surface Sb thereof. The release film 100a of the present embodiment may effectively prevent ESD in a mold process.

Meanwhile, as described above, the first external conductive filler 120out1 on the lower surface Sb of the base film 110 may form roughness on the lower surface Sb of the base film 110. In addition, the roughness on the lower surface Sb of the base film 110 may be transferred to the surface of the molding resin in the mold process to prevent chip transparency defects in the semiconductor package sealed with the molding resin.

The second external conductive filler 120out2 on the upper surface St of the base film 110 may also form roughness on the upper surface St of the base film 110. However, because the upper surface St of the base film 110 is attached to an inner surface of a mold, roughness on the upper surface St of the base film 110 does not have a function of transferring and giving roughness to the molding resin, but contributes to increasing a peeling effect. In other words, when the release film 100a is separated from the mold, peeling may easily take place due to the roughness formed on the upper surface St of the base film 110.

As a result, the release film 100a of the present embodiment may prevent ESD defects in the mold process during semiconductor package manufacturing, and may solve a chip transparency in a finally released product in the form of a package. For reference, ESD defects may result from a decrease in bandwidth of a semiconductor device and thinning of an ESD protection circuit, and the chip transparency may be attributed to the lightness and thinness of the semiconductor package. The ESD defects may be solved by giving the release film conductive properties. In addition, the chip transparency of the semiconductor package may be solved by providing roughness to the surface of the molding resin constituting the outer shape of the semiconductor package. The release film 100a of the present embodiment provides conductive properties to the release film 100a through the conductive filler 120′, thereby preventing ESD defects in the mold process. In addition, roughness may be formed on the lower surface Sb of the base film 110 through the conductive filler 120′ and transferred and given to the surface of the molding resin in the mold process, thereby preventing chip transparency defects in the semiconductor package.

The release film 100a of the present embodiment may include the conductive filler 120′ in the base film 110 for antistatic properties, that is, an ESD prevention function, while having a single layer shape. In addition, because the conductive filler 120′ has a hollow shape, the roughness of the release film 100a may increase. The conductive filler 120′ may have the various structures as those described above with reference to FIGS. 3A to 3F.

The release film 100a of the present embodiment may also be manufactured by an extrusion method or a casting method depending on the type of resin. In the case of the extrusion method, for example, ETFE resin, PET resin, PBT resin, and the like may be used. In the extrusion method, the release film may be manufactured by melting a resin for the base film, adding a conductive filler thereto and mixed, and then extruding the mixture. Meanwhile, in the case of the casting method, for example, a PTFE resin may be used. In the casting method, the release film may be manufactured by mixing a resin for a base film with a conductive filler in a solvent and then performing a film casting process thereon.

In the release film 100a of the present embodiment, surface resistance may be about 10⁴ Ω/sq to about 10¹² Ω/sq. In the unit of surface resistance, “sq” is an abbreviation of square, which may refer to cm². However, the surface resistance of the release film 100a is not limited to the above numerical range. In addition, in the release film 100a of the present embodiment, surface roughness may be about 0.5 μm to about 10 μm. Here, the surface roughness may be a value based on average roughness. However, the surface roughness of the release film 100a is not limited to the above numerical range.

Referring to FIG. 5B, a release film 100b of the present embodiment is different from the release film 100 of FIG. 1B in that a conductive filler 120″ is disposed on the upper surface St of the base film 110 in a protruding structure and the conductive filler is not disposed inside the base film 110. In an embodiment, the release film 100b of the present embodiment may include the base film 110 and the conductive filler 120″. In addition, the conductive filler 120″ may include a first external conductive filler 120out1 on the lower surface Sb of the base film 110 and a second external conductive filler 120out2 on the upper surface St of the base film 110. The functions of the first external conductive filler 120out1 and the second external conductive filler 120out2 are the same as those described above with reference to FIG. 5A. The conductive filler 120″ may have the various structures as those described above with reference to FIGS. 3A to 3F.

Meanwhile, the release film 100b of the present embodiment may not include an internal conductive filler. Accordingly, although not shown, a separate conductive path structure may be included between the upper surface St and the lower surface Sb of the base film 110. For example, a plurality of metal wires passing through the base film 110 may be disposed in the base film 110. In addition, ends of each of the metal wires may be exposed from the upper surface St and the lower surface Stb of the base film 110.

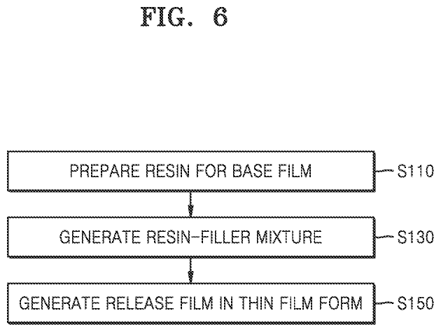

FIG. 6 is a flowchart schematically illustrating a process of a method for manufacturing a release film according to an embodiment. The process is described with reference to FIGS. 1B, 5A, and 5B.

Referring to FIG. 6, in the method for manufacturing a release film of the present embodiment, first, a resin for a base film is prepared (S110). In the method for manufacturing a release film of the present embodiment, the resin for a base film may be any one of ETFE resin, PET resin, PBT resin, and PTTE resin. However, in a subsequent process, when the extrusion method is used, the ETFE resin, the PET resin, the PBT resin, etc. may be used as the resin for a base film, and when the casting method is used, the PTTE resin may be used as the resin for a base film. However, in the method for manufacturing a release film of the present embodiment, the material of the resin for a base film is not limited to the resins mentioned above. For example, the resin for a base film may include various types of UV-curable resins or thermosetting resins.

Next, a resin-filler mixture is generated (S130). The resin-filler mixture refers to a state in which a resin for a base film is mixed with a conductive filler, and may be in a fluid state. For example, in the case of manufacturing a release film by using an extrusion method, the resin-filler mixture may be in a state in which a conductive filler is mixed with a resin for a base film in a melted state. In addition, in the case of manufacturing a release film by using the casting method, the resin-filler mixture may be in a state in which a resin for a base film is mixed with a conductive filler in a solvent.

After the resin-filler mixture is formed, a release film in the form of a thin film is generated by using the resin-filler mixture (S150). The release film in the form of a thin film may have a form in which the conductive filler 120, the conductive filler 120′, or the conductive filler 120″ are included in the base film 110, like the release film 100, the release film 100a, or the release film 100b of FIGS. 1B, 5A, and 5B. Accordingly, the release film in the form of a thin film may have a single-layer structure and include roughness due to external conductive fillers of the conductive filler (e.g., conductive filler 120, conductive filler 120′, or conductive filler 120″) on the upper surface St and/or the lower surface Sb of the base film 110. In addition, the release film in the form of a thin film may include a conductive path by internal conductive fillers of the conductive filler (e.g., the conductive filler 120 or the conductive filler 120′) between the upper surface St and the lower surface Sb of the base film 110, or a separate conductive path structure (e.g., a plurality of metal wires) as described above with reference to the release film 100b of FIG. 5B.

Meanwhile, in the method for manufacturing a release film of the present embodiment, the release film in the form of a thin film may be produced through an extrusion method. A process of manufacturing a release film through the extrusion method is described in more detail in with reference to FIGS. 7A and 7B below. In addition, in the method for manufacturing a release film of the present embodiment, the release film in the form of a thin film may be generated through a casting method. The process of manufacturing a release film through the casting method is described in more detail with reference to FIGS. 8A to 8C below.

In the method for manufacturing a release film of the present embodiment, while the release film is manufactured to have a single-layer structure through the process described above, roughness and a conductive path may be provided to the single-layer release film. Accordingly, in the method for manufacturing a release film of the present embodiment, a separate process of giving roughness may not be necessary, and also, a coating process of an AS layer may be unnecessary. As a result, because the method for manufacturing a release film of the present embodiment is advantageous in terms of cost and time, manufacturing cost of the release film may be significantly reduced. In addition, because the release film according to the method for manufacturing a release film of the present embodiment does not have an AS layer, peeling between the base film and the AS layer in the mold process, the defect of the release film due to the AS layer, and contamination of the mold may be fundamentally solved.

FIG. 7A is a flowchart illustrating in more detail an operation of producing a resin-filler mixture based on an extrusion method in the method of manufacturing a release film of FIG. 6, and FIG. 7B is a conceptual diagram of an extrusion apparatus used in the operation of manufacturing a release film in the form of a thin film. FIGS. 7A and 7B are described with reference to FIG. 6 and some repeated descriptions given above with reference to FIG. 6 are briefly given or omitted.

Referring to FIG. 7A, the resin-filler mixture generating operation (S130) of FIG. 6 may include a fluid resin generating operation (S131) and a conductive filler mixing operation (S133). Referring to the resin-filler mixture generating operation (S130), first, a fluid resin is generated (S131). Here, the fluid resin may be produced by melting a resin for a base film. The resin for a base film may be, for example, an ETFE resin, a PET resin, or a PBT resin. Of course, the material of the resin for a base film is not limited to the materials described above.

Next, a conductive filler is mixed with the fluid resin (S133). The conductive filler may be a metal-based filler or a carbon-based filler. The metal-based filler may include, for example, a metal filler and a metal oxide filler having conductivity. Meanwhile, the carbon-based filler may include carbon black (CB), carbon fiber (CF), carbon nanotube (CNT), and the like. However, the material of the conductive filler is not limited to the materials described above. In this manner, the resin-filler mixture may be produced by mixing the conductive filler with the fluid resin in a molten state.

Referring to FIG. 7B, after the resin-filler mixture R-Fcom. is produced in a resin-filler mixture producing operation (S130) of FIG. 6, a release film in the form of a thin film may be generated using the resin-filler mixture through an extrusion method in a release film generating operation (S150) of FIG. 6. In an embodiment, the extrusion method may be performed using an extrusion apparatus 1000. The extrusion apparatus 1000 may include an injection unit 1100 (e.g., an injector), a body unit 1200 (e.g., a body), and a laminator unit 1300 (e.g., a laminator).

The injection unit 1100 is a portion into which the resin-filler mixture R-Fcom. is injected, and may have a structure in which an upper portion thereof is wide and a lower portion thereof is narrow, similar to a funnel. However, a structure of the injection unit 1100 is not limited thereto. The body unit 1200 is a portion through which the resin-filler mixture R-Fcom. flows, and a screw-type rotating body is disposed therein, so that the resin-filler mixture R-Fcom. may move from the injection unit 1100 to the laminator unit 1300 according to rotation of the rotating body.

The laminator unit 1300 may also be referred to as a T-die, and may correspond to a portion in which the resin-filler mixture R-Fcom. is pulled out as an initial film 100′ in the form of a thin film. A long and narrow exit hole is provided in a lower portion of the laminator unit 1300, and as the resin-filler mixture R-Fcom. is ejected through the exit hole by a compression force, the initial film 100′ in the form of a thin film may be formed. Meanwhile, the initial film 100′ in the form of a thin film ejected through the laminator unit 1300 may be completed as the final release film (e.g., the release film 100, the release film 100a, or the release film 100b) through a curing process.

FIG. 8A is a flowchart illustrating in more detail an operation of producing a resin-filler mixture based on a casting method in the method for manufacturing a release film of FIG. 6, FIG. 8B is a conceptual diagram of a casting process corresponding thereto, and FIG. 8C is a conceptual diagram of a casting process used in an operation of manufacturing a release film in the form of a thin film. FIGS. 8A, 8B, and 8C are described with reference to FIG. 6 and some repeated descriptions given above with reference to FIG. 6 are briefly given or omitted.

Referring to FIGS. 8A and 8B, in the method for manufacturing a release film using a casting method, a resin-filler mixture generating operation (S130) of FIG. 6 may be referred to as dope preparation. In addition, the resin-filler mixture generating operation (S130) may include an operation (S132) of mixing a resin for a base film with a conductive filler in a solvent, an operation (S134) of feeding a solution with a filter, and an operation (S136) of filtering the solution.

Referring to the resin-filler mixture generating operation (S130) of FIG. 6 with reference to FIG. 8B, in a mixing section (Mixing) corresponding to the operation (S132) of mixing a resin for a base film with a conductive filler in a solvent, a resin R for a base film is mixed with a conductive filler F in a solvent Sv within a tank to be dissolved. Next, in a feeding section (Feeding) corresponding to the operation (S134) of feeding a solution Su to a filter Fu, the solution Su prepared by dissolving the resin R for a base film with the conductive filler F in the solvent Sv is fed to the filter Fu. In a filtration section (Filtration) corresponding to the operation (S136) of filtering the solution Su, unnecessary components are removed from the solution Su using the filter Fu, and a final resin-filler mixture R-Fcom. is generated.

Referring to FIG. 8C, after the resin-filler mixture R-Fcom. is generated in the resin-filler mixture generating operation (S130) of FIG. 6, a release film in the form of a thin film may be generated using the resin-filler mixture through a casting method in the release film generation step (S150) of FIG. 6. In an embodiment, the casting method in the release film generating operation (S150) may be performed through a film casting process by a casting apparatus. The film casting process may include a dispensing section (Dispensing), a coating/drying section (Coating/Drying), and a winding section (Winding).

In the dispensing section (Dispensing), the resin-filler mixture R-Fcom. may be dispensed onto a conveyor belt C.B. through a dispenser. The conveyor belt C.B. may be, for example, a stainless steel belt. The resin-filler mixture R-Fcom. may be spread thinly and widely on the conveyor belt C.B. through rotation of the conveyor belt C.B.

In the coating/drying section (Coating/Drying), the solvent may be removed from the resin-filler mixture R-Fcom. through drying. In FIG. 8C, the arrows and dashed lines in the upper part may refer to exhaust drying air (EDA) that is removed through a drying process. Here, the drying may include a process of UV curing or thermal curing. Meanwhile, in the coating/drying section (Coating/Drying), if coating is required, coating may be performed. However, in the method for manufacturing a release film of the present embodiment, because an AS layer is unnecessary, coating may not be performed in the coating/drying section (Coating/Drying). Through the coating/drying section (Coating/Drying), the release film (e.g., the release film 100, the release film 100a, or the release film 100b) may be completed.

Thereafter, in the winding section (Winding), the release film (e.g., the release film 100, the release film 100a, or the release film 100b) may be wound on a roll, such as a mother roll M.R. The release film (e.g., the release film 100, the release film 100a, or the release film 100b) wound on the mother roll M.R. may be cut and used by a required amount in a subsequent mold process.

While non-limiting example embodiments of the present disclosure have been particularly shown and described, it will be understood that various changes in form and details may be made therein without departing from the spirit and scope of the present disclosure.

1. A release film for a mold process, the release film comprising:
a base film; and
a plurality of conductive fillers that are in or on the base film, the plurality of conductive fillers comprising external conductive fillers that are on at least one from among an upper surface and a lower surface of the base film, such that the external conductive fillers provide roughness to the at least one from among the upper surface and the lower surface of the base film,
wherein a conductive path is formed between the upper surface and the lower surface of the base film.

2. The release film of claim 1, wherein at least a portion of the external conductive fillers on the at least one from among the upper surface and the lower surface of the base film protrudes from the at least one from among the upper surface and the lower surface of the base film.

3. The release film of claim 1, wherein the plurality of conductive fillers further comprises internal conductive fillers that are inside the base film,
wherein the external conductive fillers comprise first external conductive fillers on the upper surface of the base film, and second external conductive fillers on the lower surface of the base film, and
wherein the first external conductive fillers on the upper surface of the base film are connected to the second external conductive fillers on the lower surface of the base film through the internal conductive fillers that are inside the base film.

4. The release film of claim 1, wherein at least some of the plurality of conductive fillers are hollow conductive fillers having an empty inside.

5. The release film of claim 1, wherein at least some of the plurality of conductive fillers have a shape having an empty inside due to a template being removed through an open hole of the shape.

6. The release film of claim 1, wherein the plurality of conductive fillers comprise at least one from among carbon black, carbon fiber, carbon nano-tube, conductive metal oxide, and metal.

7. The release film of claim 1, wherein the base film comprises any one of an ethylene tetrafluoroethylene (ETFE) resin, a polyethylene terephthalate (PET) resin, a polybutylene terephthalate (PBT) resin, and a poly tetrafluoroethylene (PTTE) resin.

8. The release film of claim 1, wherein the base film has a thickness of 30 μm to 150 μm.

9. The release film of claim 1, wherein a surface resistance of the release film is 10⁴ Ω/sq to 10¹² Ω/sq.

10. The release film of claim 1, wherein a surface roughness of the release film is 0.5 μm to 10 μm.

11. A molding system comprising:
the release film of claim 1;
a mold; and
a molding resin,
wherein the release film is attached to the mold, and the roughness of any one from among the upper surface and the lower surface of the base film, due to the external conductive fillers, is transferred to a surface of the molding resin.

12. A release film for a mold process, the release film comprising:
a base film as a monolayer; and
a plurality of conductive fillers, the plurality of conductive fillers comprising:
internal conductive fillers inside the base film;
first external conductive fillers on an upper surface of the base film; and
second external conductive fillers on a lower surface of the base film,
wherein at least a portion of the first external conductive fillers and at least a portion of the second external conductive fillers protrude from the upper surface and the lower surface of the base film, respectively, and
wherein the first external conductive fillers on the upper surface are connected to the second external conductive fillers on the lower surface through the internal conductive fillers that are inside the base film.

13. The release film of claim 12, wherein at least some of the plurality of conductive fillers are a hollow conductive filler having an empty inside and comprises an open hole.

14. The release film of claim 13, wherein
the plurality of conductive fillers comprises at least one from among carbon black, carbon fiber, carbon nano-tube, conductive metal oxide, and metal, and
the base film comprises any one of an ethylene tetrafluoroethylene (ETFE) resin, a polyethylene terephthalate (PET) resin, a polybutylene terephthalate (PBT) resin, and a poly tetrafluoroethylene (PTTE) resin.

15. The release film of claim 13, wherein a surface resistance of the release film is 10⁴ Ω/sq to 10¹² Ω/sq, and a surface roughness of the release film is 0.5 μm to 10 μm.

16. A molding system comprising:
the release film of claim 13;
a mold configured to perform the mold process; and
a molding resin,
wherein the first external conductive fillers and the second external conductive fillers provide roughness to the upper surface and the lower surface of the base film, respectively,
wherein a conductive path is formed between the upper surface and the lower surface by the internal conductive fillers,
wherein the release film is attached to the mold, and
wherein the release film transfers the roughness of at least one from among the upper surface and the lower surface of the base film to a surface of the molding resin such as to prevent chip transparency and prevent electrostatic discharge (ESD) defects through the conductive path.

17.-27. (canceled)
